(19) United States
(12) Patent Application Publication
(10) Pub. No.: US 2009/0174320 A1
(43) Pub. Date: Jul. 9, 2009

(54) DISPLAY DEVICE HAVING IMPROVED LUMINANCE BY REFLECTING LEAKED LIGHT

(75) Inventor: Keum-Nam KIM, Suwon-si (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Suwon-si (KR)

(21) Appl. No.: 12/334,884

(22) Filed: Dec. 15, 2008

(30) Foreign Application Priority Data
Jan. 8, 2008 (KR) 2008-2111

(51) Int. Cl. H01J 1/62; H01L 29/786

(52) U.S. Cl. 313/504; 257/E29.273; 257/40

(57) ABSTRACT

A display device includes a substrate, a first layer on the substrate, organic light emitting elements on the substrate, and a condensing member. The condensing member is formed on the first layer and disposed between the organic light emitting elements. The condensing member condenses light emitted from the organic light emitting element in a light emitting direction of the display device.

### CROSS-REFERENCE TO RELATED APPLICATION

This application claims priority to and the benefit of Korean Patent Application No. 2008-2111 filed in the Korean Intellectual Property Office on Jan. 8, 2008, the contents of which are incorporated herein by reference.

### BACKGROUND OF THE INVENTION

1. Field of the Invention

An aspect of the present invention relates to a display device, and more particularly, to a display device for improving luminous efficiency by reflecting leaked light in a light emitting direction.

2. Description of the Related Art

Among various display panels, a display panel using organic light emitting elements (OLED) along with semiconductor technology have received particular attention.

An active matrix OLED display using organic light emitting elements individually controls each of the pixels by arranging pixels on a substrate in a matrix form and disposing a thin film transistor (TFT) at each of the pixels.

Such an OLED display is classified as a top emission type and a bottom emission type according to a light emitting direction.

The OLED display must emit light outputted from a unit pixel in a light emitting direction in order to sustain a luminescence characteristic at a predetermined level that a consumer desires. In actuality, some of the emitted light from a unit pixel leaks, and the leaked light propagates along a layer disposed around an organic light emitting element, for example a planarization layer, to an adjacent unit pixel. As a result, the adjacent unit pixel undesirably emits light. Accordingly, the display quality of the OLED display deteriorates due to light emitted from the adjacent unit pixel.

Since the OLED display has been commonly used in small size and mobile electronic devices such as a portable (cellular) phone, a personal digital assistant (PDA), and a portable multimedia player (PMP), the OLED display must have a small volume for superior portability.

The above information disclosed in this Background section is only for enhancement of understanding of the background of the invention, and therefore it may contain information that does not form the prior art that is already known in this country to a person of ordinary skill in the art.

### SUMMARY OF THE INVENTION

An aspect of the present invention has been made in an effort to provide a display device having advantages of improving emission efficiency using a simple manufacturing process.

An exemplary embodiment of the present invention provides a display device including a substrate, a first layer on the substrate, organic light emitting elements on the substrate, and a condensing member. The condensing member is formed on the first layer and disposed between the organic light emitting elements. The condensing member condenses light emitted from the organic light emitting elements in a light emitting direction.

According to an aspect of the present invention, the condensing member may include a barrier disposed at an edge of the organic light emitting element, and a reflective layer formed on a surface of the barrier.

According to an aspect of the present invention, the display device may further include a thin film transistor connected to the organic light emitting element. The first layer may be an insulating layer formed between the organic light emitting element and the thin film transistor, and the barrier may protrude from the insulating layer.

According to an aspect of the present invention, the barrier may be made of the same material as the insulating layer.

According to an aspect of the present invention, the barrier may be disposed to surround the organic light emitting element.

According to an aspect of the present invention, the organic light emitting element may include a first pixel electrode, an organic emission layer, and a second pixel electrode, and the reflective layer may be elongated from the first pixel electrode. The reflective layer may be made of the same material as the first pixel electrode.

According to an aspect of the present invention, the first pixel electrode may include one selected from the group consisting of aluminum (Al), nickel (Ni), chromium (Cr), silver (Ag), gold (Au), an aluminum alloy (Al-alloy), a silver alloy (Ag-alloy), and a gold alloy (Au-alloy), and the second pixel electrode is transparent. The second pixel electrode may include one selected from the group consisting of indium tin oxide (ITO), indium zinc oxide (IZO), and MgAg.

According to an aspect of the present invention, the display device may further include a thin film transistor connected to the organic light emitting element and a pixel defining layer formed on the first layer, wherein the pixel defining layer has a first opening and the organic light emitting element is disposed therein. The first layer may be an insulating layer formed between the organic light emitting element and the thin film transistor, and the barrier may be formed as the pixel defining layer.

According to an aspect of the present invention, a channel may be formed at the pixel defining layer between the organic light emitting elements. The channel may be formed by a second opening where the reflective layer is disposed.

According to an aspect of the present invention, the organic light emitting element may include a first pixel electrode, an organic emission layer, and a second pixel electrode, and the reflective layer may be elongated from the second pixel electrode.

According to an aspect of the present invention, the reflective layer may be disposed in the channel. The reflective layer may be made of the same material as the second pixel electrode.

According to an aspect of the present invention, the first pixel electrode may be transparent because it is made of one selected from the group consisting of indium tin oxide (ITO), indium zinc oxide (IZO), and MgAg. The second pixel electrode may include one selected from the group consisting of aluminum (Al), nickel (Ni), chromium (Cr), silver (Ag), gold (Au), an aluminum alloy (Al-alloy), a silver alloy (Ag-alloy), and a gold alloy (Au-alloy).

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1A to FIG. 1N show cross-sectional views of a display device according to the first exemplary embodiment of the present invention for illustrating a manufacturing process thereof; and

FIG. 2A to FIG. 2F are cross-sectional views of a display device according to the second exemplary embodiment of the present invention for illustrating a manufacturing process thereof.

### DETAILED DESCRIPTION OF THE EMBODIMENTS

An aspect of the present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

Accordingly, the drawings and description are to be regarded as illustrative in nature and not restrictive. Like reference numerals designate like elements throughout the specification.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Throughout this specification and the claims that follow, when it is described that an element is “coupled” to another element, it may indicate that an element is “electrically coupled” to another element with a third element interposed as well as that an element is “directly coupled” to the another element. Throughout the specification, if something is described to “include constituent elements”, it may indicate that other constituent elements are included unless it is described not to include the other constituent elements.

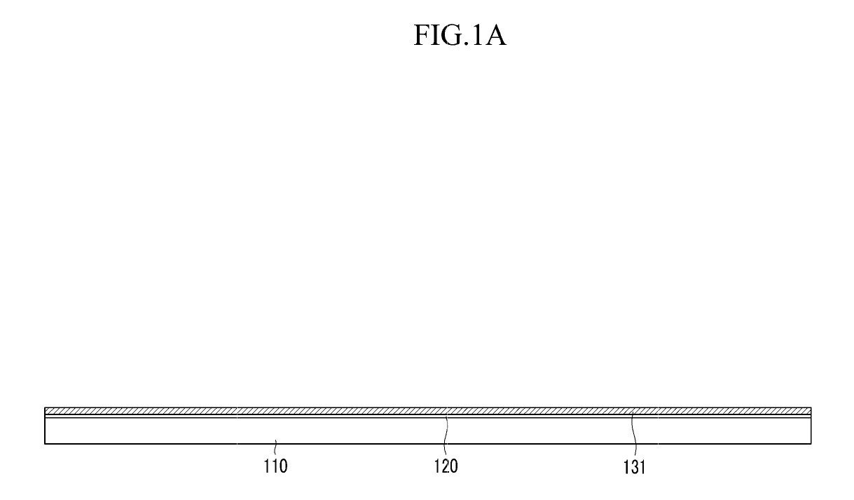

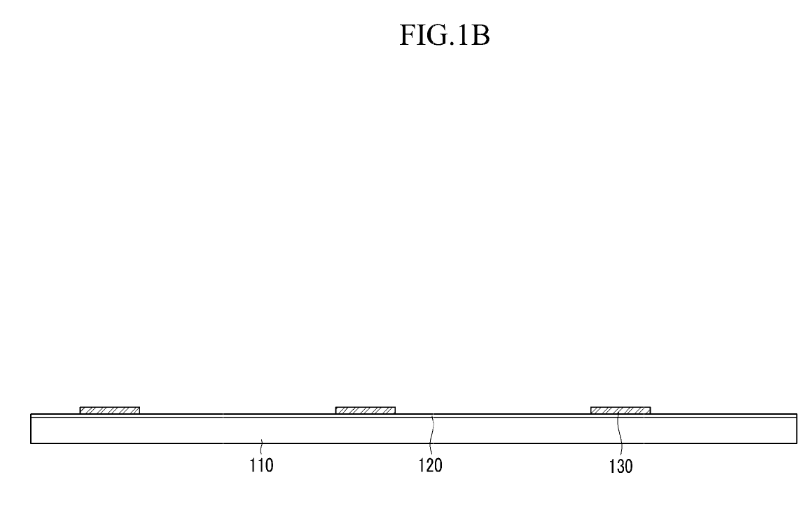

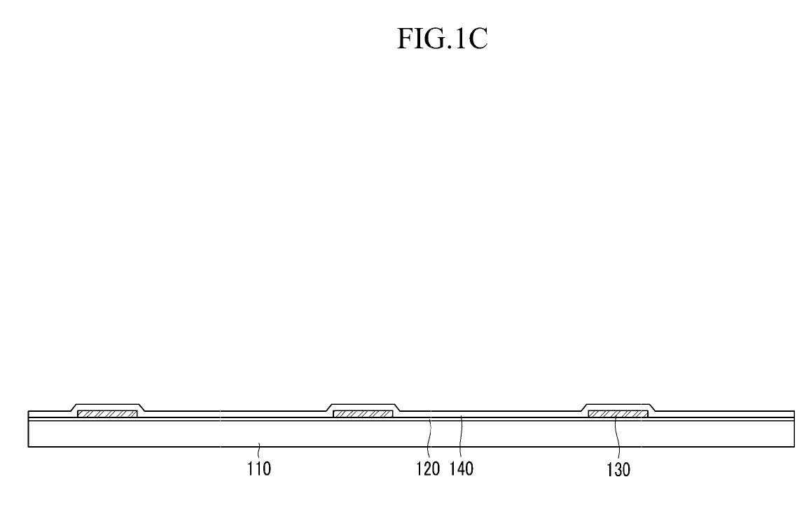

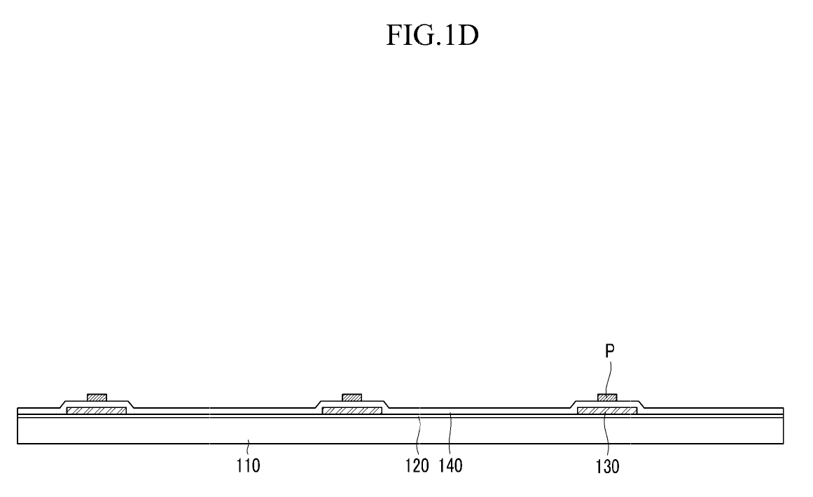

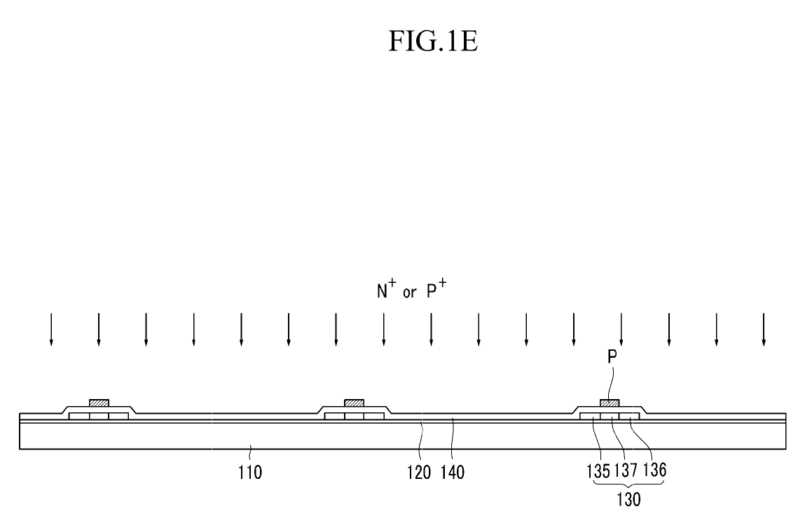

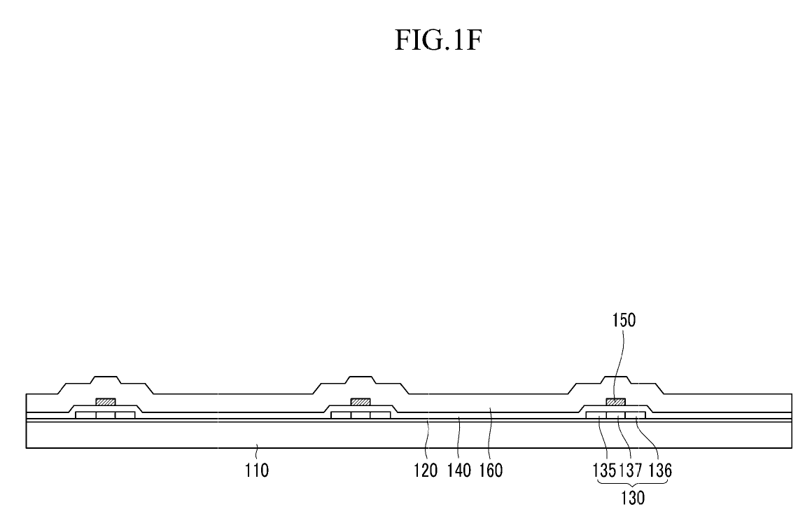

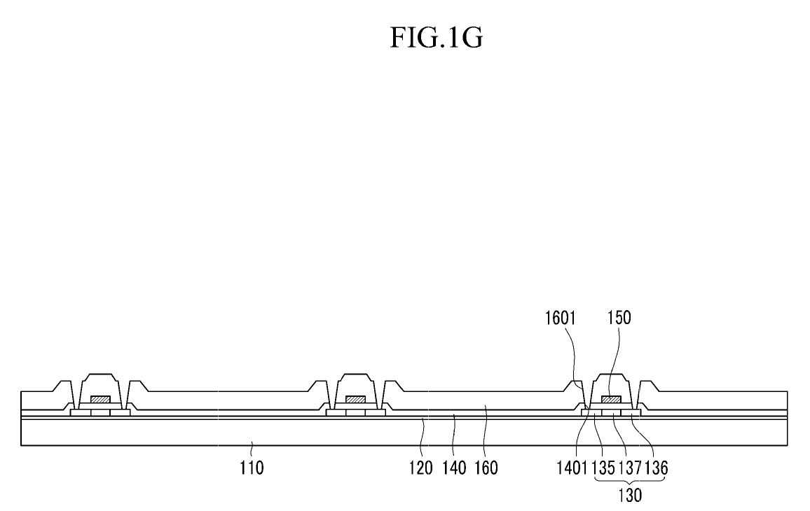

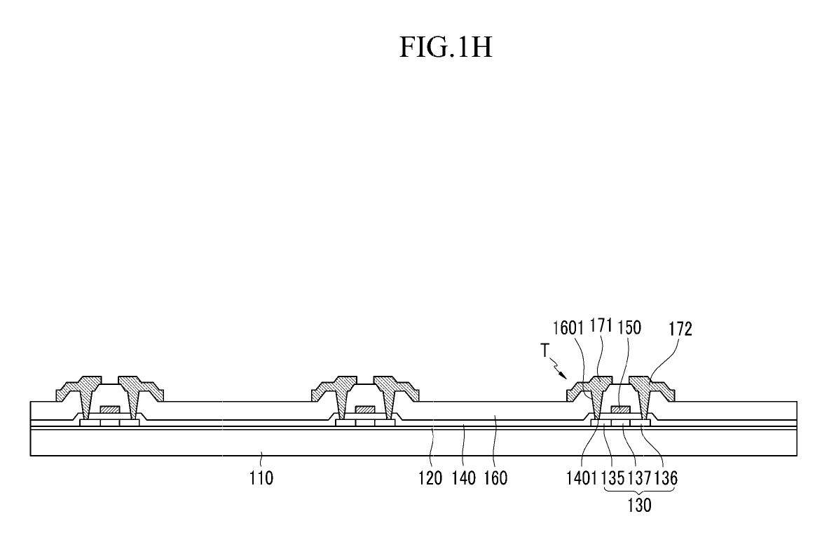

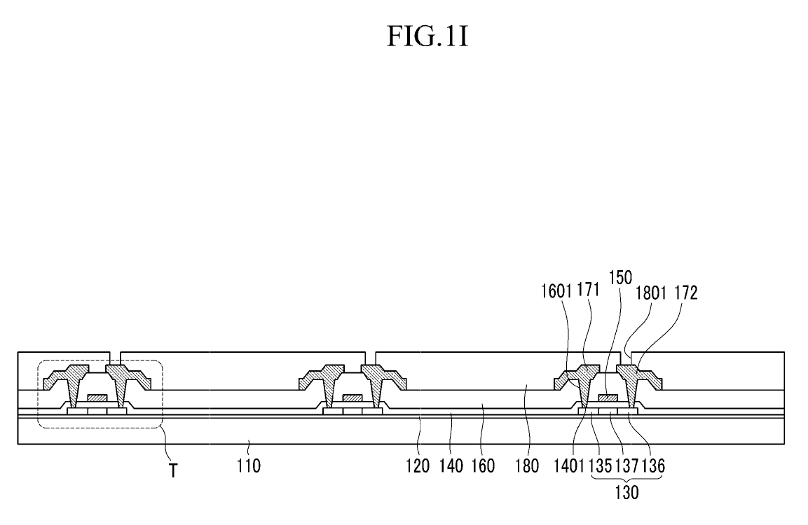

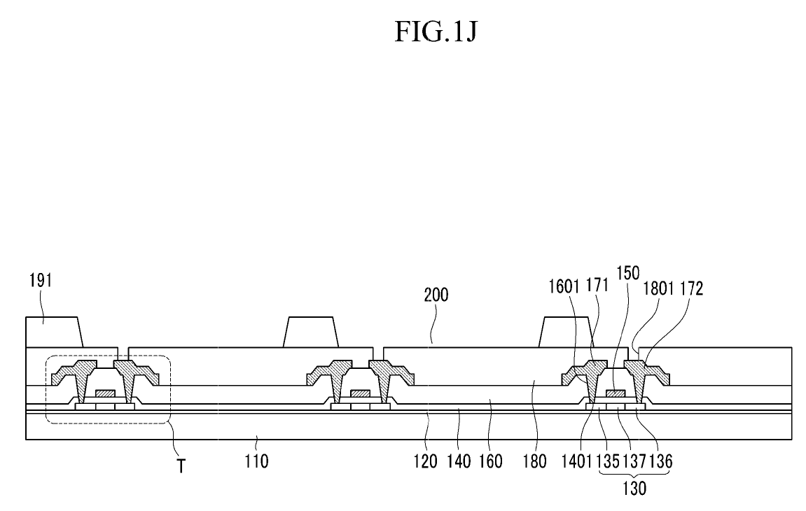

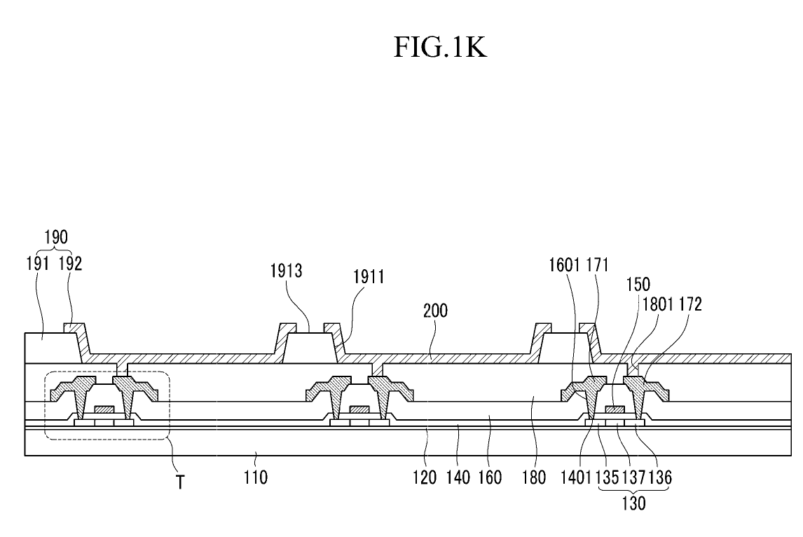

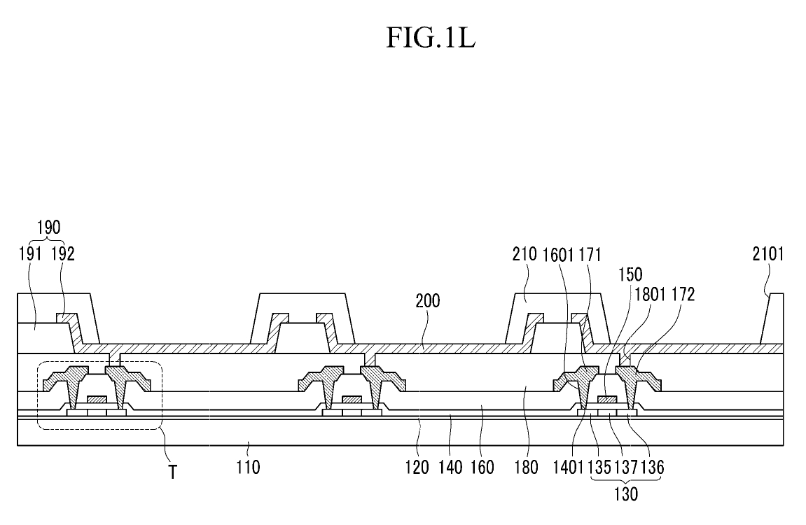

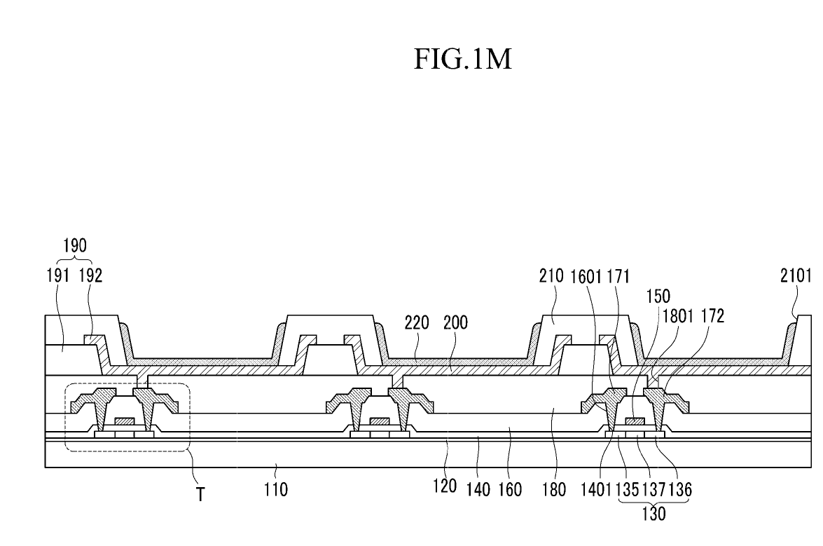

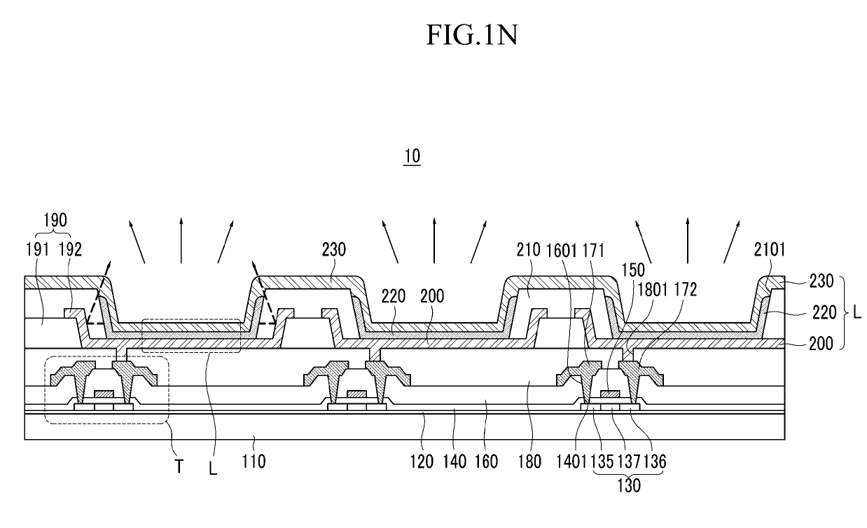

FIG. 1A to FIG. 1N show a manufacturing process of a display device 10 according to the first exemplary embodiment of the present invention. The display device 10 is a top emission organic light emitting diode (OLED) display, where an organic light emitting element emits light in a direction opposite to that of a substrate 110 having thin film transistors. The display device 10 includes a condensing member for condensing light emitted from an organic light emitting element formed on a first layer on the substrate 110 in a light emitting direction. Here, the first layer may be a planarization layer formed on the substrate 110 as an insulating layer to cover a thin film transistor. However, the first layer is not limited to the planarization layer.

Referring to FIG. 1A, a buffer layer 120 is formed on the substrate 110, and an amorphous silicon layer 131 is formed on the buffer layer 120. A dehydrogenation process is performed on the amorphous silicon layer 131 at a temperature from 400° C. to 550° C.

The substrate 110 may be made of an insulating material or a metallic material. The insulating material may be glass or plastic, and the metallic material may be stainless using steel (SUS).

The buffer layer 120 prevents impurities on the substrate 110 from being diffused to the amorphous silicon layer 131 while crystallizing the amorphous silicon layer 131. For example, the buffer layer 120 may be formed of a silicon nitride (SiN) layer or a layer stacked with silicon nitride (SiN) and silicon oxide (SiO₂).

If the dehydrogenation process is performed before forming and crystallizing the amorphous silicon layer 131, hydrogen included in the amorphous silicon layer 131 can be removed in advance. Accordingly, it is possible to prevent defects from being generated due to hydrogen separated therefrom while crystallizing.

Referring to FIG. 1B, a polysilicon layer is formed by crystallizing the amorphous silicon layer 131 through the crystallization process, and a semiconductor layer 130 is formed by patterning the polysilicon layer. Here, the polysilicon may be formed by crystallizing the amorphous silicon layer 131 using an excimer laser annealing method (ELA). If the semiconductor layer 130 is made of the amorphous silicon layer as described above, the semiconductor layer 130 may advantageously have higher electron or hole mobility than a semiconductor layer 130 made of a polysilicon layer.

Referring to FIG. 1C, a gate insulating layer 140 is formed on the substrate 110 after forming the semiconductor layer 130. The gate insulating layer 140 may be formed using chemical vapor deposition (CVD). The gate insulating layer 140 is formed by forming a silicon oxide layer through injecting a mixed gas of a silane gas and an oxygen gas in a CVD chamber or by forming a silicon nitride layer by injecting a mixed gas of a silane gas and a nitride gas in a CVD chamber.

After forming the gate insulating layer 140, a mask pattern P is formed as shown in FIG. 1D. The mask pattern P may be formed by coating a photoresist on an entire surface of the gate insulating layer 140 and exposing and developing the photoresist with a predetermined pattern. The mask pattern P is formed to expose a predetermined region of the semiconductor layer 130, for example, a source/drain region.

Referring to FIG. 1E, a source region 135 and a drain region 136 are formed on respective edges of the semiconductor layer 130 by injecting an N-type impurity or a P-type impurity on the gate insulating layer having the mask pattern P formed thereon. Here, a center region between the source region 135 and the drain region 136 operates as a channel region 137. According to a P-type impurity injection process or an N-type impurity injection process, a p-channel metal oxide semiconductor (PMOS) thin film transistor or an n-channel metal oxide semiconductor (NMOS) thin film transistor may be formed.

Referring to FIG. 1F, a gate electrode 150 is formed on the gate insulating layer corresponding to the center region of the semiconductor layer 130 after removing the mask pattern P, and an interlayer insulating layer 160 is formed to cover the gate electrode 150. The gate electrode 150 may be made of metal, for example one selected from the group consisting of MoW, Al, Cr, and Al/Cr.

Referring to FIG. 1G, a first contact hole 1401 and a second contact hole 1601 are formed by patterning the interlayer insulating layer 160 and the gate insulating layer 140 through an exposing and developing process using the mask, and an etching process. As a result, the source region 135 and the drain region 136 are exposed through the contact holes 1401 and 1601.

Referring to FIG. 1H, a source electrode 171 and a drain electrode 172 are formed to be electrically connected to the source region 135 and the drain region 136, respectively through the first contact hole 1401 and the second contact hole 1601 on the interlayer insulating layer 160. The source electrode 171 and the drain electrode 172 may be formed of a metal, for example, of Ti/Al or Ti/Al/Ti.

As a result, the thin film transistor T is manufactured.

Hereinafter, an organic light emitting element L will be described. The organic light emitting element L is formed on the thin film transistor T and electrically connected to a part of the thin film transistor T. Here, the thin film transistor T and the organic light emitting element L form a unit pixel of the display device 10.

Referring to FIG. 11, a planarization layer 180 is formed on the interlayer insulating layer 160 to cover the thin film transistor T of FIG. 1H. Further, a via hole 1801 is formed through an exposing and developing process using a mask, and an etching process.

Referring to FIG. 1J, a barrier 191 is formed by forming a layer on the planarization layer 180 using an insulating material of a predetermined thickness and patterning the formed layer. The barrier 191 is formed in a form of a lattice-type barrier rib on an edge of the organic light emitting element L to cover the organic light emitting element L in all directions. Here, the barrier 191 may be made of the same material as the planarization layer 180 that is formed directly under the barrier 191.

The barrier 191 may be patterned on the planarization layer 180 after forming the planarization layer 180 by using the mask used for forming the planarization layer 180 and the other mask. However, a method for forming the barrier is not limited thereto in the present embodiment. For example, the planarization layer and the barrier may be simultaneously formed using a halftone mask that can control an exposure thickness of a photosensitive film through a light emission amount. This method allows a simpler manufacturing process than the former method using two masks.

Referring to FIG. 1K, a first pixel electrode 200 is formed on the planarization layer 180. The first pixel electrode 200 is electrically connected to the drain electrode 172 of the thin film transistor T through the via hole 1801.

The first pixel electrode 200 may be elongated not only along the upper part of the planarization layer 180 but also along an inclined side 1911 of the barrier 191 and/or the upper side 1913 thereof. In the present exemplary embodiment, the first pixel electrode 200 is formed on the inclined side 1911 and the upper side 1913 of the barrier 191. Here, a part of the first pixel electrode 200, that is, a part of the first pixel electrode 200 formed on the inclined side 1911 of the barrier 191, forms a condensing member 190 with the barrier 191. This part condenses light emitted from the organic light emitting element L in a light emitting direction.

Referring to FIG. 1L, a pixel defining layer 210 is formed on the planarization layer 180 to cover a reflective layer 192 and the barrier 191. An opening 2101 is formed by patterning a part of the pixel defining layer 210. As a result, a part of the first pixel electrode 200 is exposed through the opening 2101. The pixel defining layer 210 electrically isolates the first pixel electrode 200 of a pixel from that of an adjacent pixel.

Referring to FIG. 1M, an organic emission layer 220 is formed on the first pixel electrode 200 through the opening 2101 formed on the pixel defining layer 210.

The organic emission layer 220 may further include an emission layer for emitting light and an organic layer disposed at an upper part and a lower part of the organic emission layer for effectively transferring carriers of holes and electrons to the light emitting layer. For example, the organic layer may include at least one of a hole injection layer HIL and a hole transport layer HTL formed between an emission layer and the first pixel electrode 200, and an electron transfer layer and an electron transport layer ETL formed between the emission layer and a second pixel electrode 230.

Referring to FIG. 1N, the second pixel electrode 230 is formed on the entire surface of the substrate 110 for commonly supplying a negative voltage to a plurality of unit pixels. For example, the first pixel electrode 200 performs a function of injecting holes, and the second pixel electrode 230 performs a function of injecting electrons. As a result, the first pixel electrode 200, the organic emission layer 220, and the second pixel electrode 230 are sequentially formed, thereby forming the organic light emitting element L.

The second pixel electrode 230 is made of a transparent conductive layer depending on a light emitting direction of the organic light emitting element L (see a solid line arrow in FIG. 1N). For example, the transparent conductive layer may be made of IZO, ITO, or MgAg.

Meanwhile, the condensing member 190 according to the present exemplary embodiment prevents light emitted from the organic emission layer 220 of each pixel from being leaked to adjacent pixels through the pixel defining layer 210. That is, the condensing member 190 condenses light emitted from the organic emission layer 220 in a light emitting direction of the display device 10.

It is preferable, but not necessary to form the barrier 191 to be higher than the organic emission layer 220 in a stacking direction of the organic light emitting element L as a reference. As described above, the barrier 191 is formed to surround the organic light emitting element L.

The reflective layer 192 condenses light emitted from the organic emission layer 220 in a light emitting direction of the display device 10 by reflecting the light emitted from the organic emission layer 220 along a dotted line arrow direction of FIG. 1N. For this, the reflective layer 192 may be formed of a material having high reflectivity, for example, aluminum (Al), an aluminum alloy (Al-alloy), silver (Ag), a silver alloy (Ag-alloy), gold (Au), or a gold alloy (Au-alloy).

The display device 10 of the present exemplary embodiment of the present invention is a top emission display device 10 including the first pixel electrode 200 made of a reflective material for improving luminous efficiency of the display device 10. In this case, the reflective layer 192 may be formed by elongating the first pixel electrode 200 to the inclined side of the barrier 191 as shown in FIG. 1L. However, the present exemplary embodiment of the present invention is not limited thereto. Therefore, the reflective layer and metal thereof can be modified as long as the reflective layer has reflectivity.

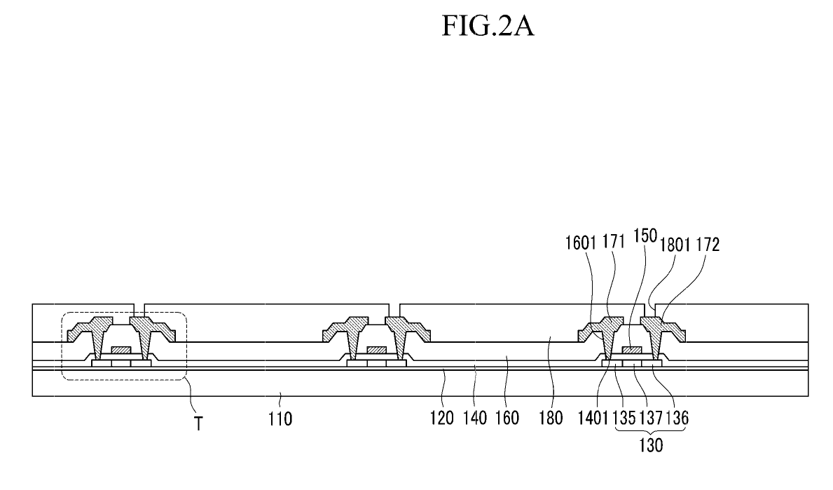

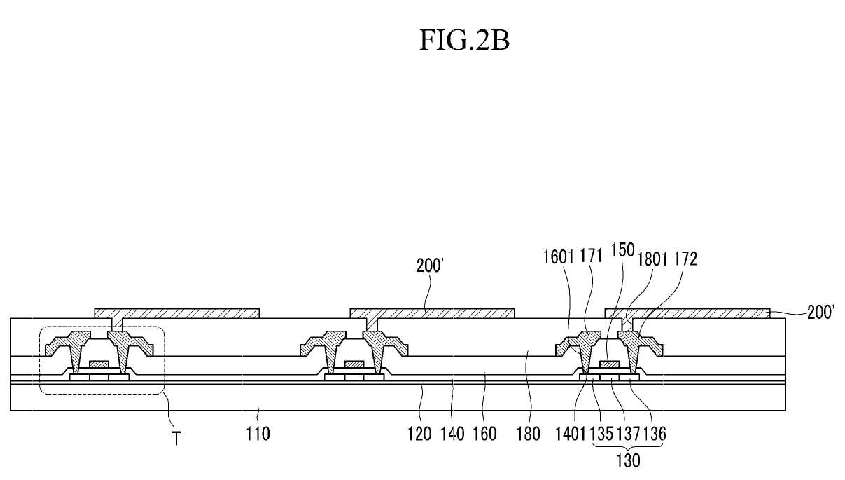

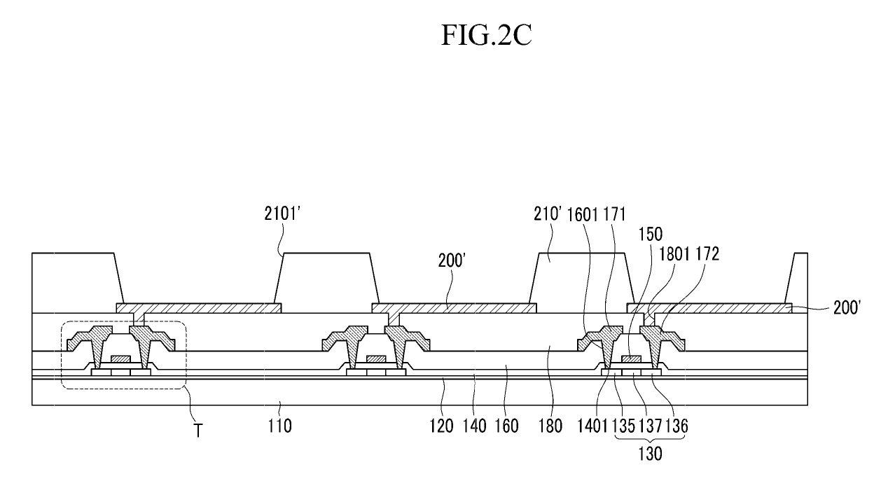

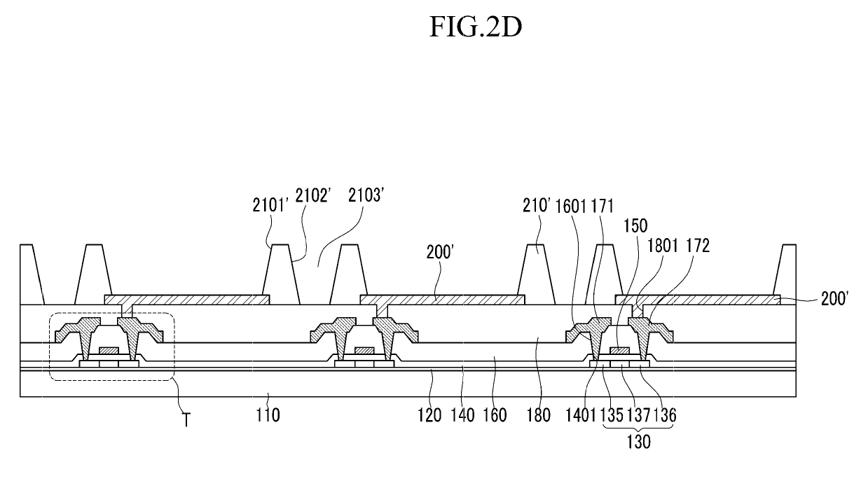

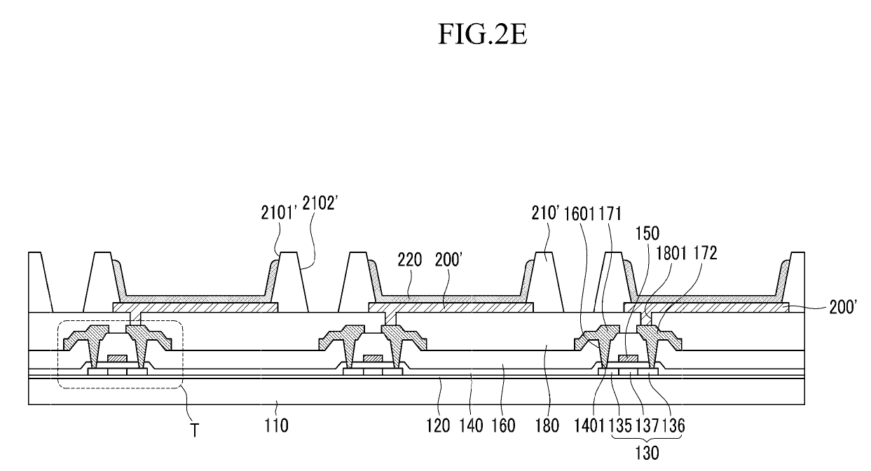

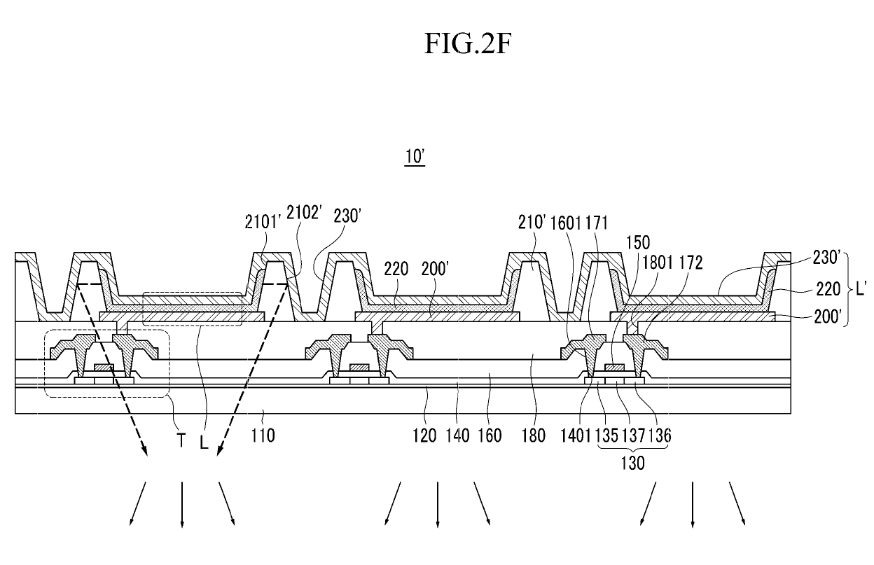

FIG. 2A to FIG. 2F show a manufacturing process of a display device 10′ according to the second exemplary embodiment of the present invention. The display device 10′ is a bottom emission OLED display that emits light from an organic light emitting element through a substrate 110 after it passes through a thin film transistor T.

For convenience, a description of the manufacturing of a thin film transistor T is omitted in FIG. 2A to FIG. 2F. Like reference numerals denote like constituent elements in FIG. 1A through FIG. 2F, and detailed descriptions of the same constituent elements are omitted. The display device 10′ also includes the condensing member, which is included in the display device 10 according to the first exemplary embodiment.

Referring to FIG. 2A, a planarization layer 180 is formed on an interlayer insulating layer 160 to cover a thin film transistor T, and a via hole 1801 is formed by patterning the planarization layer 180.

Referring to FIG. 2B, a first pixel electrode 200′ is formed on the planarization layer. The first pixel electrode 200′ is electrically connected to the drain electrode 172 through the via hole 1801. The first pixel electrode 200′ may be formed of a transparent electrode made of indium tin oxide (ITO), indium zinc oxide (IZO), or Mg/Ag depending on a light emitting direction (see a solid line arrow direction of FIG. 2F) of the bottom emission display device 10′.

Referring to FIG. 2C, a pixel defining layer 210′ is formed on the planarization layer 180 to cover the first pixel electrode 200′. Thereafter, a first opening 2101′ is formed by patterning the pixel defining layer 210′. The first opening 2101′ is formed on a part of the first pixel electrode 200′ exposing the first pixel electrode 200′ through the first opening 2101′.

Referring to FIG. 2D, a channel 2103′ including a second opening 2102′ is formed by patterning the pixel defining layer 210′. The channel 2103′ is formed between organic light emitting elements L′ of each unit pixel located near the thin film transistor T, and a part of the planarization layer 180 is exposed through the second opening 2101′. The channel 2103′ surrounds a unit pixel along the edge of the unit pixel if the display device 10′ is observed in a plane view.

The channel may be formed as an opening as in the second exemplary embodiment, or the channel may be formed as a groove.

The pixel defining layer 210′ electrically isolates the first pixel electrodes 200′ of adjacent unit pixels.

Referring to FIG. 2E, an organic emission layer 220 is formed on the first pixel electrode 200′ and on the first opening 2101′.

The organic emission layer 220 may further include an emission layer for emitting light, and an organic layer disposed at an upper part and a lower part of the emission layer for effectively transferring holes or electrons to the emission layer. For example, the organic layer may include at least one of a hole injection layer HIL and a hole transport layer HTL, which are formed between the emission layer and the first pixel electrode 210′, and an electron transport layer ETL and an electron injection layer EIL, which are formed between the emission layer and a second pixel electrode 230′.

Referring to FIG. 2F, the second pixel electrode 230′ is formed on the entire surface of the substrate in order to commonly supply a negative voltage to a plurality of unit pixels. In the second exemplary embodiment, the first pixel electrode 200′ performs a function of injecting holes, and the second pixel electrode 230′ performs a function of injecting electrons. As a result, the first pixel electrode 200′, the organic emission layer 220, and the second pixel electrode 230′ are sequentially formed, thereby forming the organic light emitting element L′.

The second pixel electrode 230′ may be made of a reflective material depending on a light emitting direction of the organic light emitting element L′ (see a solid line arrow in FIG. 2). For example, the second pixel electrode 230′ may be made of aluminum (Al), an aluminum alloy (Al-alloy), silver (Ag), a silver alloy (Ag-alloy), gold (Au), or a gold alloy (Au-alloy).

In the second exemplary embodiment, the second pixel electrode 230′ is arranged in the second opening 2102′ of the pixel defining layer 210′. That is, the second pixel electrode 230′ is formed on the pixel defining layer 210′ and the planarization layer 180. The pixel defining layer 210′ operates as a barrier that surrounds the organic light emitting element L′ having the organic emission layer 220, and the second pixel electrode 230′ formed in the second opening 2102′ operates as a reflective layer.

As described above, the display device 10′ reflects light propagating along the pixel defining layer 210′ among light outputted from the organic emission layer 220 by the second pixel electrode 230′ formed in the second opening 2102′ in a dotted line arrow direction of FIG. 2F, thereby condensing the light in a light emitting direction of the display device 10′. That is, the pixel defining layer 210′ and the second pixel electrode 230′ operate as a condensing member that condenses light that is outputted from the organic emission layer 220 in a light emitting direction of the display device 10′. Therefore, the display device 10′ can improve light emitting efficiency.

A display device according to an exemplary embodiment of the present invention can form a condensing member to surround an organic emission layer without additional constituent elements.

That is, the condensing member condenses light emitted from a unit pixel in a light emitting direction by preventing light that is outputted from an organic emission layer from being leaked to adjacent pixels. Therefore, light emitting efficiency can be improved.

Also, overall volume of a display device is not expanded because the condensing member is formed using constituent elements included in a typical display device. Therefore, the adaptability of a display device to a portable product can be improved. Furthermore, the manufacturing cost can be prevented from rising by simplifying the manufacturing process thereof.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A display device comprising:
a substrate;
a first layer on the substrate;
organic light emitting elements on the substrate; and
a condensing member formed on the first layer and disposed between the organic light emitting elements for condensing light emitted from the organic light emitting elements in a light emitting direction of the display device.

2. The display device of claim 1, wherein the condensing member includes:
a barrier disposed at an edge of the organic light emitting element; and
a reflective layer formed on a surface of the barrier.

3. The display device of claim 2, further comprising a thin film transistor connected to the organic light emitting element,
wherein the first layer is an insulating layer formed between the organic light emitting element and the thin film transistor, and
the barrier protrudes from the insulating layer.

4. The display device of claim 3, wherein the barrier is made of the same material as the insulating layer.

5. The display device of claim 2, wherein the barrier is disposed to surround the organic light emitting element.

6. The display device of claim 2, wherein the organic light emitting element includes a first pixel electrode, an organic emission layer, and a second pixel electrode, and the reflective layer is elongated from the first pixel electrode.

7. The display device of claim 6, wherein the reflective layer is made of the same material as the first pixel electrode.

8. The display device of claim 6, wherein the first pixel electrode includes one selected from the group consisting of aluminum (Al), nickel (Ni), chromium (Cr), silver (Ag), gold (Au), an aluminum alloy (Al-alloy), a silver alloy (Ag-alloy), and a gold alloy (Au-alloy), and the second pixel electrode is transparent.

9. The display device of claim 8, wherein the second pixel electrode includes one selected from the group consisting of indium tin oxide (ITO), indium zinc oxide (IZO), and MgAg.

10. The display device of claim 2, further comprising thin film transistors connected to the organic light emitting elements and a pixel defining layer formed on the first layer, wherein the pixel defining layer has first openings where the organic light emitting elements are disposed,
wherein the first layer is an insulating layer formed between the organic light emitting elements and the thin film transistors, and the barrier is formed as the pixel defining layer.

11. The display device of claim 10, wherein a channel is formed at the pixel defining layer between the organic light emitting elements.

12. The display device of claim 11, wherein the channel is formed by a second opening where the reflective layer is disposed.

13. The display device of claim 2, wherein the organic light emitting element includes a first pixel electrode, an organic emission layer, and a second pixel electrode, and the reflective layer is elongated from the second pixel electrode.

14. The display device of claim 13, wherein the reflective layer is disposed in the channel.

15. The display device of claim 14, wherein the reflective layer is made of the same material as the second pixel electrode.

16. The display device of claim 15, wherein the first pixel electrode is transparent, and the second pixel electrode includes one selected from the group consisting of aluminum (Al), nickel (Ni), chromium (Cr), silver (Ag), gold (Au), an aluminum alloy (Al-alloy), a silver alloy (Ag-alloy), and a gold alloy (Au-alloy).

17. The display device of claim 16, wherein the first pixel electrode includes one selected from the group consisting of indium tin oxide (ITO), indium zinc oxide (IZO), and MgAg.

18. A display device comprising:
a substrate;
organic light emitting elements formed on the substrate;
a first layer formed on the organic light emitting elements;
thin film transistors formed on the first layer and electrically coupled to the organic light emitting elements via holes formed on the first layer; and
a condensing member disposed between the organic light emitting elements condensing light emitted from the organic light emitting elements in a light emitting direction of the display device.

19. The display device according to claim 18, wherein the condensing member includes a barrier formed on the first layer, and a reflective layer formed on sides of the barrier.

20. The display device according to claim 18, wherein the barrier is a lattice-type barrier rib and is formed on edges of the organic light emitting elements.

21. The display device according to claim 18, wherein the organic light emitting elements include a first pixel electrode, an organic emission layer and a second pixel electrode.

22. The display device according to claim 19, wherein the reflective layer includes one selected from aluminum (Al), an aluminum alloy (Al-alloy), silver (Ag), a silver alloy (Ag-alloy), gold (Au), and a gold alloy (Au-alloy).
